(19) United States
(12) Patent Application Publication
(10) Pub. No.: US 2025/0210391 A1
(43) Pub. Date: Jun. 26, 2025

(54) SUBSTRATE PROCESSING SYSTEM AND SUBSTRATE PROCESSING METHOD

(71) Applicant: Tokyo Electron Limited, Tokyo (JP)

(72) Inventors: Yukiyoshi SAITO, Kumamoto (JP); Masahiro NAKAHARADA, Kumamoto (JP)

(21) Appl. No.: 18/985,542

(22) Filed: Dec. 18, 2024

(30) Foreign Application Priority Data
Dec. 20, 2023 (JP) 2023-214960

(51) Int. Cl. H01L 21/677; H01L 21/67

(52) U.S. Cl. CPC H01L 21/67745; H01L 21/67057; H01L 21/67086

(57) ABSTRACT

A substrate processing system includes: a loading/unloading section that loads and unloads a cassette accommodating a plurality of substrates; a batch processing section that collectively processes the substrates; a single-wafer processing section that processes the substrates one by one; a substrate transfer section that transfers the substrates from the loading/unloading section to the batch processing section and the single-wafer processing section; and a substrate standby section that transfers the substrates from the batch processing section to the single-wafer processing section. The substrate standby section includes: a standby stage including a first standby region and a second standby region; a first transport device that collectively transports the substrates from the batch processing section to the first standby region; and a first movement device that moves the substrates from the first standby region to the second standby region. The second standby region includes a first processing liquid supply.

### CROSS-REFERENCE TO RELATED APPLICATIONS

This application is based on and claims priority from Japanese Patent Application No. 2023-214960, filed on Dec. 20, 2023, with the Japan Patent Office, the disclosure of which is incorporated herein in its entirety by reference.

### TECHNICAL FIELD

The present disclosure relates to a substrate processing system and a substrate processing method.

### BACKGROUND

A substrate processing system including a batch processing section and a single-wafer processing section is known (see, e.g., Japanese Patent Laid-Open Publication No. 2023-121571). The batch processing section performs a batch processing in which a lot including a plurality of substrates is processed all at once. The single-wafer processing section performs a single-wafer processing in which substrates are processed one by one. In the substrate processing system, a complex processing including a batch processing and a single-wafer processing, and a single-wafer processing are performed in parallel.

### SUMMARY

According to an aspect of the present disclosure, a substrate processing system includes: a loading/unloading section that loads and unloads a cassette accommodating a plurality of substrates; a batch processing section that collectively processes the plurality of substrates; a single-wafer processing section that processes the plurality of substrates one by one; a substrate transfer section that transfers the plurality of substrates from the loading/unloading section to the batch processing section and the single-wafer processing section; and a substrate standby section that transfers the plurality of substrates from the batch processing section to the single-wafer processing section. The substrate standby section includes: a standby stage including a first standby region that disposes thereon the substrate loaded from the batch processing section, and a second standby region that is provided vertically adjacent to the first standby region, and disposes thereon the substrate to be unloaded to the single-wafer processing section; a first transport device that collectively transports the substrate from the batch processing section to the first standby region; and a first movement device that moves the substrate from the first standby region to the second standby region. The second standby region includes a first processing liquid supply that supplies a first processing liquid to a top surface of the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating a substrate processing system according to an embodiment.

FIG. 2 is a sectional view illustrating a configuration including a delivery stage, a standby stage, and a single-wafer processing section.

FIGS. 3A and 3B are views illustrating a second standby region.

FIG. 4 is a flow chart illustrating a substrate processing method according to the embodiment.

FIG. 5 is a plan view illustrating the operation of complex processing.

FIG. 6 is a view illustrating the transport flow of substrates in complex processing.

FIG. 7 is a plan view illustrating the operation of single-wafer processing.

FIG. 8 is a view illustrating the transport flow of substrates in single-wafer processing.

FIG. 9 is a view (1) illustrating the movement operation of substrates in the standby stage.

FIG. 10 is a view (2) illustrating the movement operation of substrates in the standby stage.

FIG. 11 is a view (3) illustrating the movement operation of substrates in the standby stage.

FIG. 12 is a view (4) illustrating the movement operation of substrates in the standby stage.

FIG. 13 is a view (5) illustrating the movement operation of substrates in the standby stage.

FIG. 14 is a view (6) illustrating the movement operation of substrates in the standby stage.

FIG. 15 is a view (7) illustrating the movement operation of substrates in the standby stage.

FIG. 16 is a view (1) illustrating the movement operation of substrates in the delivery stage.

FIG. 17 is a view (2) illustrating the movement operation of substrates in the delivery stage.

FIG. 18 is a view (3) illustrating the movement operation of substrates in the delivery stage.

FIG. 19 is a view (4) illustrating the movement operation of substrates in the delivery stage.

FIG. 20 is a view (5) illustrating the movement operation of substrates in the delivery stage.

FIG. 21 is a view (6) illustrating the movement operation of substrates in the delivery stage.

FIG. 22 is a view (7) illustrating the movement operation of substrates in the delivery stage.

FIG. 23 is a view (8) illustrating the movement operation of substrates in the delivery stage.

FIG. 24 is a view (9) illustrating the movement operation of substrates in the delivery stage.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, the non-limiting embodiment of the present disclosure will be described with reference to accompanying drawings. In all the accompanying drawings, the same or corresponding members or components are denoted by the same or corresponding reference numerals, and redundant descriptions thereof will be omitted.

### [Substrate Processing System]

### (Overall Configuration)

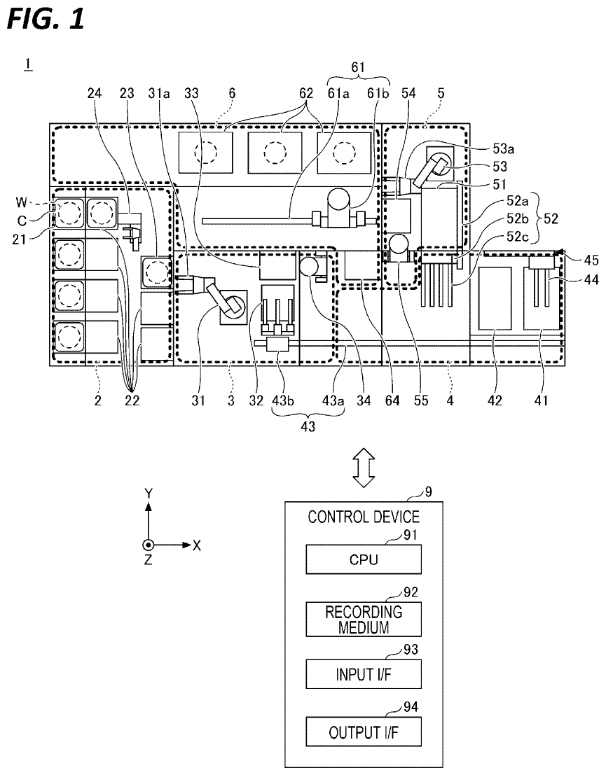

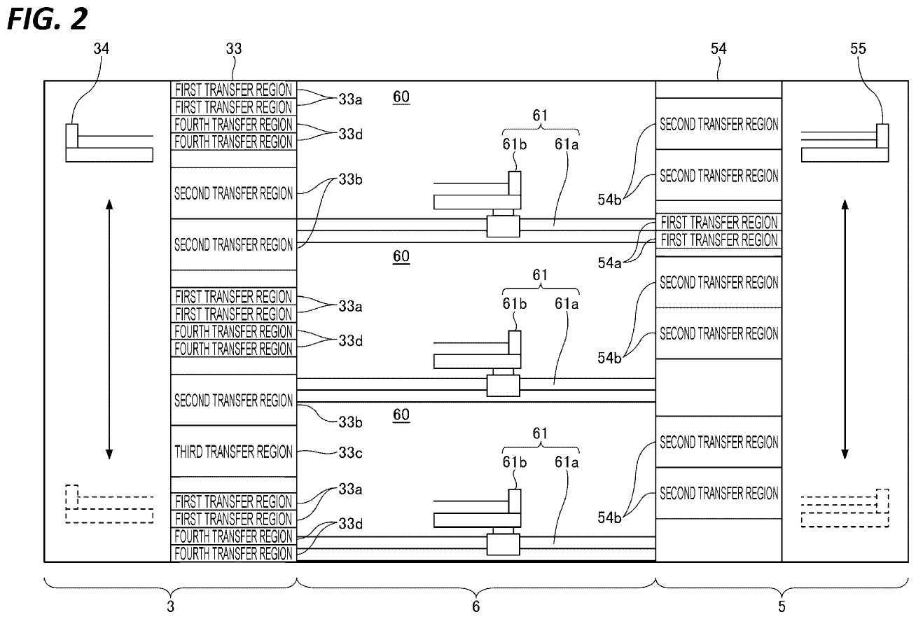

A substrate processing system 1 according to an embodiment will be described with reference to FIGS. 1 and 2. FIG. 1 is a plan view illustrating the substrate processing system 1 according to the embodiment. FIG. 2 is a sectional view illustrating a configuration including a delivery stage 33, a standby stage 54, and a single-wafer processing section 6.

As illustrated in FIG. 1, the substrate processing system 1 includes a loading/unloading section 2, a substrate transfer section 3, a batch processing section 4, a substrate standby section 5, the single-wafer processing section 6, and a control device 9.

The loading/unloading section 2 serves as both a loading section and an unloading section. In this case, the substrate processing system 1 may be reduced in size. The loading/unloading section 2 includes a load port 21, a stocker 22, a loader 23, and a cassette transport device 24.

The load port 21 is disposed on the negative side of the loading/unloading section 2 in the X-axis direction. A plurality of (e.g., four) load ports 21 is disposed along the Y-axis direction. Meanwhile, the number of load ports 21 is not particularly limited. On the load port 21, a cassette C is placed. The cassette C accommodates a plurality of (e.g., 25) substrates W, and is loaded to or unloaded from the load port 21. Inside the cassette C, the substrates W are horizontally held, and are held in the vertical direction at a second pitch P2 (P2=N×P1) which is N times a first pitch P1. N is a natural number of 2 or more, and in the present embodiment, N is 2, but may be 3 or more.

A plurality of (e.g., four) stockers 22 is disposed along the Y-axis direction, in the center of the loading/unloading section 2 in the X-axis direction. A plurality of (e.g., two) stockers 22 is disposed adjacent to the substrate transfer section 3 along the Y-axis direction, on the positive side of the loading/unloading section 2 in the X-axis direction. The stockers 22 may be arranged in the vertical direction in multiple tiers. The stocker 22 temporarily stores, for example, a cassette C where substrates W are accommodated before cleaning treatment, or a cassette C whose inside is empty after substrates W are taken out. Also, the number of stockers 22 is not particularly limited.

The loader 23 is adjacent to the substrate transfer section 3, and is disposed on the positive side of the loading/unloading section 2 in the X-axis direction. On the loader 23, the cassette C is placed. The loader 23 is provided with a lid opening/closing mechanism (not illustrated) for opening and closing the lid of the cassette C. A plurality of loaders 23 may be provided. The loaders 23 may be arranged in the vertical direction in multiple stages.

The cassette transport device 24 conveys the cassettes C between the load ports 21, the stockers 22, and the loaders 23. The cassette transport device 24 is, for example, an articulated transport robot.

The substrate transfer section 3 is disposed on the positive side of the loading/unloading section 2 in the X-axis direction. In the substrate transfer section 3, substrates W are transported between the loading/unloading section 2, the batch processing section 4, and the single-wafer processing section 6. The substrate transfer section 3 includes a transfer device 31, a lot forming unit 32, the delivery stage 33, and a second movement device 34.

The transfer device 31 transports substrates W between the cassette C placed on the loader 23, the lot forming unit 32, and the delivery stage 33. The transfer device 31 distributes the substrates W accommodated in the cassette C placed on the loader 23, to a third transfer region 33c of the delivery stage 33 for the transport to the single-wafer processing section 6, and to the lot forming unit 32 for the transport to the batch processing section 4. The transfer device 31 includes a multi-axis (e.g., six-axis) arm robot, and has a substrate holding arm 31a on the distal end thereof. The substrate holding arm 31a has a plurality of holding claws (not illustrated) capable of holding a plurality of (e.g., 25) substrates W. The substrate holding arm 31a may keep any position and posture in a three-dimensional space while holding the substrates W with the holding claws.

The lot forming unit 32 is disposed on the positive side of the substrate transfer section 3 in the X-axis direction. The lot forming unit 32 holds the plurality of substrates W at the first pitch P1, and forms a lot L. The lot forming unit 32 constitutes a part of a transfer stage. The lot forming unit 32 is an example of a fifth transfer region.

The delivery stage 33 is adjacent to the single-wafer processing section 6, and is disposed on the positive side of the substrate transfer section 3 in the Y-axis direction. The delivery stage 33 constitutes a part of the transfer stage. As illustrated in FIG. 2, the delivery stage 33 includes a first transfer region 33a, a second transfer region 33b, a third transfer region 33c, and a fourth transfer region 33d. The first transfer region 33a, the second transfer region 33b, the third transfer region 33c, and the fourth transfer region 33d are arranged side by side in the vertical direction.

On the first transfer region 33a, a substrate W loaded from the single-wafer processing section 6 is placed. The first transfer regions 33a are provided for individual processing unit blocks 60 of the single-wafer processing section 6. For example, two first transfer regions 33a are provided at locations accessible by a transport arm 61b of the upper processing unit block 60, and accessible by the second movement device 34. For example, two first transfer regions 33a are provided at locations accessible by a transport arm 61b of the middle processing unit block 60, and accessible by the second movement device 34. For example, two first transfer regions 33a are provided at locations accessible by a transport arm 61b of the lower processing unit block 60, and accessible by the second movement device 34.

In the configuration of each first transfer region 33a, a first number of substrates W may be placed. The first number is, for example, the same as the number of substrates W that may be held by the transport arm 61b. The first number is, for example, one. The first transfer region 33a receives the substrate W from the transport arm 61b, and temporarily stores the substrate W until the substrate W is transferred to the second transfer region 33b.

On the second transfer region 33b, substrates W to be unloaded to the loading/unloading section 2 are placed. The second transfer region 33b is provided at a location accessible by the transfer device 31 and the second movement device 34. For example, three second transfer regions 33b are provided at different locations in the vertical direction.

In the configuration of each second transfer region 33b, a second number of substrates W may be placed. The second number is, for example, the same as the number of substrates W accommodated in the cassette C. The second number is, for example, 25. The second transfer region 33b receives the substrates W from the second movement device 34, and temporarily stores the substrates W until the substrates W are transferred to the loading/unloading section 2.

On the third transfer region 33c, substrates W loaded from the loading/unloading section 2 are placed and substrates W to be unloaded to the loading/unloading section 2 are placed. The third transfer region 33c is provided at a location accessible by the transfer device 31 and the second movement device 34. For example, one third transfer region 33c is provided.

In the configuration of the third transfer region 33c, a third number of substrates W may be placed. The third number is, for example, the same as the number of substrates W accommodated in the cassette C. The third number is, for example, 25. The third transfer region 33c receives the substrates W from the transfer device 31, and temporarily stores the substrates W until the substrates W are transferred to the fourth transfer region 33d. The third transfer region 33c receives the substrates W from the second movement device 34, and temporarily stores the substrates W until the substrates W are transferred to the loading/unloading section 2.

On the fourth transfer region 33d, a substrate W to be unloaded to the single-wafer processing section 6 is placed, and a substrate W loaded from the single-wafer processing section 6 is placed. The fourth transfer regions 33d are provided for individual processing unit blocks 60 of the single-wafer processing section 6. For example, two fourth transfer regions 33d are provided at locations accessible by the transport arm 61b of the upper processing unit block 60, and accessible by the second movement device 34. For example, two fourth transfer regions 33d are provided at locations accessible by the transport arm 61b of the middle processing unit block 60 and accessible by the second movement device 34. For example, two fourth transfer regions 33d are provided at locations accessible by the transport arm 61b of the lower processing unit block 60 and accessible by the second movement device 34.

In the configuration of each fourth transfer region 33d, a fourth number of substrates W may be placed. The fourth number is, for example, the same as the number of substrates W that may be held by the transport arm 61b. The fourth number is, for example, one. The fourth transfer region 33d receives the substrate W from the second movement device 34, and temporarily stores the substrate W until the substrate W is transferred to the single-wafer processing section 6. The fourth transfer region 33d receives the substrate W from the transport arm 61b and temporarily stores the substrate W until the substrate W is transferred to the third transfer region 33c.

The second movement device 34 may access the first transfer region 33a, the second transfer region 33b, the third transfer region 33c, and the fourth transfer region 33d. The second movement device 34 may be configured to be movable along the vertical direction. The second movement device 34 moves the substrate W from the first transfer region 33a to the second transfer region 33b. The second movement device 34 moves the substrate W from the third transfer region 33c to the fourth transfer region 33d. The second movement device 34 moves the substrate W from the fourth transfer region 33d to the third transfer region 33c. The second movement device 34 may move the substrates W one by one or may collectively move the plurality of substrates W. In the latter case, the second movement device 34 collectively transports the plurality of (e.g., two) substrates W.

The batch processing section 4 is disposed on the positive side of the substrate transfer section 3 in the X-axis direction. That is, the loading/unloading section 2, the substrate transfer section 3, and the batch processing section 4 are arranged in this order from the negative side in the X-axis direction to the positive side in the X-axis direction. The batch processing section collectively processes a lot L including a plurality of (e.g., 50 or 100) substrates W at the first pitch P1. One lot L is composed of, for example, substrates W of M cassettes C. M is a natural number of 2 or more. M may be the same natural number as N or may be a natural number different from N. The batch processing section 4 includes a chemical liquid tank 41, a rinse liquid tank 42, a first lot transport device 43, a processing tool 44, and a drive device 45.

The chemical liquid tank 41 and the rinse liquid tank 42 are arranged along the X-axis direction. For example, the chemical liquid tank 41 and the rinse liquid tank 42 are aligned in this order from the positive side in the X-axis direction to the negative side in the X-axis direction. The chemical liquid tank 41 and the rinse liquid tank 42 are also collectively referred to as a processing tank. The number of chemical liquid tanks 41 and the number of rinse liquid tanks 42 are not limited to those in FIG. 1. For example, the chemical liquid tank 41 and the rinse liquid tank 42 form one set in FIG. 1, but there may be multiple sets.

The chemical liquid tank 41 stores a chemical liquid in which the lot L is immersed. The chemical liquid is, for example, an aqueous phosphoric acid solution (H₃PO₄). The aqueous phosphoric acid solution selectively etches and removes a silicon nitride film between a silicon oxide film and a silicon nitride film. The chemical liquid is not limited to the aqueous phosphoric acid solution. For example, the chemical liquid may be DHF (dilute hydrofluoric acid), BHF (a mixed solution of hydrofluoric acid and ammonium fluoride), dilute sulfuric acid, SPM (a mixed solution of sulfuric acid, hydrogen peroxide, and water), SC1 (a mixed solution of ammonia, hydrogen peroxide, and water), SC2 (a mixed solution of hydrochloric acid, hydrogen peroxide, and water), TMAH (a mixed solution of tetramethylammonium hydroxide and water), or a plating solution. The chemical liquid may be used for peeling treatment or plating treatment. There may be a plurality of chemical liquids, and the number of chemical liquids is not particularly limited.

The rinse liquid tank 42 stores a first rinse liquid in which the lot L is immersed. The first rinse liquid is pure water that removes a chemical liquid from the substrate W, and is, for example, DIW (deionized water).

The first lot transport device 43 includes a guide rail 43a, and a transport arm 43b. The guide rail 43a is disposed on the negative side of the processing tank in the Y-axis direction. The guide rail 43a extends along the horizontal direction (X-axis direction) from the substrate transfer section 3 to the batch processing section 4. The transport arm 43b moves in the horizontal direction (X-axis direction) along the guide rail 43a. The transport arm 43b may move in the vertical direction, and may rotate around the vertical axis. The transport arm 43b collectively transports the lot L between the substrate transfer section 3 and the batch processing section 4.

The processing tool 44 receives the lot L from the transport arm 43b, and holds the lot L. The processing tool 44 holds the plurality of substrates W at the first pitch P1 in the Y-axis direction, and vertically holds each of the substrates W.

The drive device 45 moves the processing tool 44 in the X-axis direction and the Z-axis direction. The processing tool 44 immerses the lot L into the chemical liquid stored in the chemical liquid tank 41, immerses the lot L into the first rinse liquid stored in the rinse liquid tank 42, and then transfers the lot L to the first lot transport device 43.

In the present embodiment, one unit of the processing tool 44 and the drive device 45 is provided, but there may be a plurality of units. In the latter case, one unit immerses the lot L into the chemical liquid stored in the chemical liquid tank 41, and another unit immerses the lot L into the first rinse liquid stored in the rinse liquid tank 42. In this case, the drive device 45 only needs to move the processing tool 44 in the Z-axis direction, and does not need to move the processing tool 44 in the X-axis direction.

The substrate standby section 5 is disposed on the positive side of the batch processing section 4 in the Y-axis direction. Through the substrate standby section 5, substrates W are transported between the batch processing section 4 and the single-wafer processing section 6. The substrate standby section 5 includes an immersion tank 51, a second lot transport device 52, a first transfer device 53, the standby stage 54, and a first movement device 55.

The immersion tank 51 is disposed outside the movement range of the transport arm 43b. For example, the immersion tank 51 is disposed at a shifted position on the positive side of the processing tank in the Y-axis direction. The immersion tank 51 stores a second rinse liquid in which the lot L is immersed. The second rinse liquid is, for example, deionized water (DIW). The substrates W are held in the second rinse liquid until the substrates W are lifted up from the second rinse liquid by the first transfer device 53. Since the substrates W exist below the liquid surface of the second rinse liquid, the surface tension of the second rinse liquid does not act on the substrates W, thereby preventing the collapse of the uneven patterns of the substrates W.

The second lot transport device 52 includes a Y-axis drive device 52a, a Z-axis drive device 52b, and a transport arm 52c.

The Y-axis drive device 52a is disposed on the positive side of the substrate standby section 5 in the X-axis direction. The Y-axis drive device 52a extends along the horizontal direction (Y-axis direction) from the substrate standby section 5 to the batch processing section 4. The Y-axis drive device 52a moves the Z-axis drive device 52b and the transport arm 52c in the Y-axis direction. The Y-axis drive device 52a may include a ball screw.

The Z-axis drive device 52b is movably attached to the Y-axis drive device 52a. The Z-axis drive device 52b moves the transport arm 52c in the Z-axis direction. The Z-axis drive device 52b may include a ball screw.

The transport arm 52c is movably attached to the Z-axis drive device 52b. The transport arm 52c receives the lot L from the transport arm 43b and holds the lot L. The transport arm 52c holds the plurality of substrates W at the first pitch P1 in the Y-axis direction, and vertically holds each of the substrates W. The transport arm 52c moves in the Y-axis direction and the Z-axis direction by the Y-axis drive device 52a and the Z-axis drive device 52b. The transport arm 52c is configured to be movable to a plurality of positions including a transfer position, an immersion position, and a standby position.

The transfer position is a position where the lot L is transferred between the transport arm 43b and the transport arm 52c. The transfer position is a position on the negative side in the Y-axis direction and on the positive side in the Z-axis direction.

The immersion position is a position where the lot L is immersed in the immersion tank 51. The immersion position is a position on the positive side of the transfer position in the Y-axis direction and on the negative side in the Z-axis direction.

The standby position is a position where the transport arm 52c waits when the transfer of the lot L and the immersion of the lot L into the immersion tank 51 are not performed. The standby position is directly below the transfer position (on the negative side in the Z-axis direction) and is a position where the movement of the transport arm 43b is not hindered. In this case, the transport arm 52c may be moved to the transfer position only by moving upwards (on the positive side in the Z-axis direction), thereby improving the throughput. The standby position may be the same position as the immersion position. In this case, particles, which may be generated by the operation of the first lot transport device 43, may be prevented from adhering to the transport arm 52c. The standby position may be a position directly above the immersion position (on the positive side in the Z-axis direction). In this way, by setting the standby position to a position different from the transfer position, it is possible to prevent the contact between the transport arm 43b and the transport arm 52c.

This second lot transport device 52 moves the transport arm 52c to the immersion position or the standby position while the first lot transport device 43 is operating. Accordingly, the contact between the transport arm 43b and the transport arm 52c may be prevented.

The first transfer device 53 collectively transports a plurality of (e.g., two) substrates W between the transport arm 52c at the immersion position, and a first standby region 54a of the standby stage 54. In this case, the time required for carrying the substrates W is shortened. As a result, the throughput is improved. The first transfer device 53 includes a multi-axis (e.g., six-axis) arm robot, and has a transport arm 53a on the distal end thereof. The transport arm 53a has a holding claw (not illustrated) capable of holding the plurality of (e.g., two) substrates W. The transport arm 53a may keep any position and posture in a three-dimensional space while holding the substrates W with the holding claw. Also, the immersion tank 51 is disposed outside the movement range of the transport arm 43b. For this reason, the transport arm 43b and the transport arm 53a do not interfere with each other. This allows one of the first lot transport device 43 and the first transfer device 53 to independently operate regardless of the operating state of the other. Therefore, the first lot transport device 43 and the first transfer device 53 may be operated at any timing, thereby reducing the time required for carrying the substrates W. As a result, the throughput is improved.

The standby stage 54 is adjacent to the single-wafer processing section 6, and is disposed on the negative side of the substrate standby section 5 in the X-axis direction. The standby stage 54 receives the substrates W from the first transfer device 53, and temporarily stores the substrates W until the substrates W are transferred to the single-wafer processing section 6. That is, the substrates W taken out of the immersion tank 51 are placed on the standby stage 54. It is desirable that the substrate W placed on the standby stage 54 is in a state where, for example, the surface is wet with the second rinse liquid. In this case, the surface tension of the second rinse liquid does not act on the substrate W, thereby suppressing the collapse of the uneven pattern of the substrate W.

As illustrated in FIG. 2, the standby stage 54 includes a first standby region 54a, and a second standby region 54b. The first standby region 54a and the second standby region 54b are arranged side by side in the vertical direction.

On the first standby region 54a, a substrate W loaded from the batch processing section 4 is placed. The first standby region 54a is provided at a location accessible by the first transfer device 53 and the first movement device 55. For example, two first standby regions 54a are provided at different locations in the vertical direction.

In the configuration of each first standby region 54a, a fifth number of substrates W may be placed. The fifth number is, for example, one. The first standby region 54a receives the substrate W from the first transfer device 53, and temporarily stores the substrate W until the substrate W is transferred to the second standby region 54b.

On the second standby region 54b, a substrate W to be unloaded to the single-wafer processing section 6 is placed. The second standby regions 54b are provided for individual processing unit blocks 60 of the single-wafer processing section 6. For example, two second standby regions 54b are provided at locations accessible by the transport arm 61b of the upper processing unit block 60, and accessible by the first movement device 55. For example, two second standby regions 54b are provided at locations accessible by the transport arm 61b of the middle processing unit block 60, and accessible by the first movement device 55. For example, two second standby regions 54b are provided at locations accessible by the transport arm 61b of the lower processing unit block 60, and accessible by the first movement device 55.

In the configuration of each second standby region 54b, a sixth number of substrates W may be placed. The sixth number is, for example, one. The second standby region 54b receives the substrate W from the first movement device 55, and temporarily stores the substrate W until the substrate W is transferred to the single-wafer processing section 6.

The first movement device 55 may access the first standby region 54a and the second standby region 54b. The first movement device 55 may be configured to be movable along the vertical direction. The first movement device 55 moves the substrate W from the first standby region 54a to the second standby region 54b. The first movement device 55 may move the substrates W one by one, or may collectively move the plurality of substrates W. In the latter case, the first movement device 55 collectively transports the plurality of (e.g., two) substrates W.

The single-wafer processing section 6 is disposed on the negative side of the substrate standby section 5 in the X-axis direction, and on the positive side of the loading/unloading section 2, the substrate transfer section 3 and the batch processing section 4 in the Y-axis direction. The single-wafer processing section 6 processes substrates W one by one. The single-wafer processing section 6 includes the processing unit blocks 60 vertically arranged in three stages. In this case, since the substrates W may be simultaneously subjected to single-wafer processing, the throughput is improved. Each processing unit block 60 includes a second transfer device 61, a liquid processing apparatus 62, and a retreat stage 64.

The second transfer device 61 transports the substrates W between the standby stage 54, the liquid processing apparatus 62, the retreat stage 64, and the delivery stage 33. The second transfer device 61 may be configured to transport the substrate W from the second standby region 54b of the standby stage 54 to the liquid processing apparatus 62. The second transfer device 61 may be configured to transport the substrate W from the liquid processing apparatus 62 to the first transfer region 33a of the delivery stage 33 when the processing on the substrate W is complex processing. The second transfer device 61 may be configured to transport the substrate W from the liquid processing apparatus 62 to the fourth transfer region 33d of the delivery stage 33 when the processing on the substrate W is single-wafer processing. The second transfer device 61 may be configured to transport the substrate W that is being transferred, to the retreat stage 64, when the liquid processing apparatus 62 is in an unavailable state during the transfer of the substrate W from the substrate standby section 5 to the liquid processing apparatus 62. The second transfer device 61 may be configured to transport the substrate W from the retreat stage 64 to the liquid processing apparatus 62 in an available state when at least one of three liquid processing apparatus 62 is in an available state after the substrate W is transported to the retreat stage 64.

The second transfer device 61 includes a guide rail 61a, and the transport arm 61b. The guide rail 61a is disposed on the negative side of the single-wafer processing section 6 in the Y-axis direction. The guide rail 61a extends along the horizontal direction (the X-axis direction) in the single-wafer processing section 6. The transport arm 61b moves along the guide rail 61a in the horizontal direction (the X-axis direction) and in the vertical direction, and rotates around the vertical axis. The number of transport arms 61b may be one or more. In the latter case, the second transfer device 61 collectively transports a plurality of (e.g., five) substrates W.

The three liquid processing apparatus 62 are arranged along the X-axis direction. Each liquid processing apparatus 62 is a single-wafer type, and processes the substrates W one by one with a processing liquid. There may be a plurality of processing liquids, for example, pure water such as DIW, and a drying liquid having a lower surface tension than pure water. The drying liquid may be, for example, alcohol such as isopropyl alcohol (IPA).

On the retreat stage 64, the substrate W unloaded from the substrate standby section 5 is placed. The retreat stage 64 is provided at a position accessible by the second transfer device 61. The retreat stage 64 is provided on, for example, the opposite side of the liquid processing apparatus 62 (on the negative side in the Y-axis direction) with the second transfer device 61 being interposed therebetween. In the configuration of the retreat stage 64, one substrate W may be placed, or a plurality of substrates W may be placed. The retreat stage 64 temporarily stores the substrate W when the liquid processing apparatus 62 is in an unavailable state during the transfer of the substrate W from the substrate standby section 5 to the liquid processing apparatus 62.

In the present embodiment, the single-wafer processing section 6 includes the processing unit blocks 60 having the same configuration, but the single-wafer processing section 6 may include the processing unit blocks 60 having different configurations. For example, the single-wafer processing section 6 may include the processing unit block 60 including a drying device as well as the liquid processing apparatus 62. The drying device is a single-wafer type, and dries the substrates W one by one with a supercritical fluid. In the present embodiment, the processing unit blocks 60 in three vertical stages are provided, but the number of processing unit blocks 60 is not limited.

The control device 9 is, for example, a computer, and includes a central processing unit (CPU) 91, and a recording medium 92 such as a memory. The recording medium 92 stores programs for controlling various processes to be executed in the substrate processing system 1. The control device 9 controls the operation of the substrate processing system 1 by causing the CPU 91 to execute the programs stored in the recording medium 92. The control device 9 includes an input interface 93, and an output interface 94. The control device 9 receives signals from the outside via the input interface 93, and transmits signals to the outside via the output interface 94.

The programs are stored in, for example, a computer-readable recording medium, and are installed from the recording medium to the recording medium 92 of the control device 9. Examples of the computer-readable recording medium may include a hard disk (HD), a flexible disk (FD), a compact disc (CD), a magneto optical disk (MO), and a memory card. Also, the programs may be downloaded from a server via the Internet, and may be installed to the recording medium 92 of the control device 9.

The control device 9 is configured to control the transfer device 31 so as to transport a plurality of substrates W accommodated in the cassette C to either the lot forming unit 32 or the delivery stage 33, based on information associated with the cassette C loaded into the loading/unloading section 2. The information may include a substrate type. For example, when the substrate type is a product substrate, the control device 9 controls the transfer device 31 so as to transport the substrates W accommodated in the cassette C to the lot forming unit 32. For example, when the substrate type is a dummy substrate, the control device 9 controls the transfer device 31 so as to transport the substrates W accommodated in the cassette C to the delivery stage 33.

### (Details of Configuration of Second Standby Region)

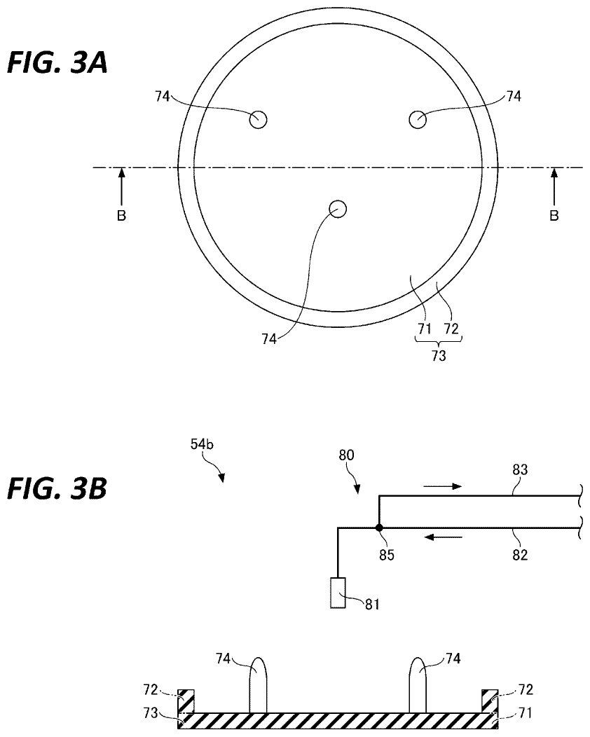

The details of the configuration of the second standby region 54b will be described with reference to FIGS. 3A and 3B. FIGS. 3A and 3B are views illustrating the second standby region 54b. FIG. 3A is a top view, and FIG. 3B is a sectional view. FIG. 3B corresponds to a sectional view taken along the B-B line in FIG. 3A.

As illustrated in FIGS. 3A and 3B, the second standby region 54b includes a pure water supply 80, a liquid receiving unit 73, and three or more pins 74. In FIG. 3A, the pure water supply 80 is omitted.

The liquid receiving unit 73 includes a bottom plate 71 and a wall portion 72. The bottom plate 71 has a disk-like shape. The wall portion 72 is annularly provided on the bottom plate 71. The pins 74 are provided on the bottom plate 71. In the present embodiment, the number of pins 74 is three, but may be four or more. The three pins 74 are arranged to form an equilateral triangle in plan view. A surface including the respective upper ends of the pins 74 is horizontal. The respective upper ends of the pins 74 are located above the upper end of the wall portion 72. In plan view, the center of the equilateral triangle formed by the three pins 74 approximately coincides with the center of the disk-shaped bottom plate 71. Above the bottom plate 71, the pins 74 support a substrate W from below.

The pure water supply 80 includes a nozzle 81, a pure water supply line 82, and a return line 83. The pure water supply line 82 is connected to the nozzle 81. The nozzle 81 ejects pure water supplied through the pure water supply line 82. A branch point 85 is provided in the pure water supply line 82, and the return line 83 is connected to the branch point 85. Even during a period in which pure water is not being ejected from the nozzle 81, pure water flows through a portion of the pure water supply line 82 upstream of the branch point 85, and the return line 83. The pure water supply 80 configured in this manner supplies pure water to the top surface of the substrate W. The pure water supply 80 is an example of a first processing liquid supply, and the pure water is an example of a first processing liquid.

The second standby region 54b has such a configuration where the substrate W is horizontally held while being in contact with the pure water.

Like the second standby region 54b, the retreat stage 64 may also include a pure water supply, a liquid receiving unit, and three or more pins. The pure water supply is an example of a second processing liquid supply, and the pure water is an example of a second processing liquid.

As described above, the substrate processing system 1 according to the embodiment includes the loading/unloading section 2, the substrate transfer section 3, the batch processing section 4, the substrate standby section 5, and the single-wafer processing section 6. The substrate standby section 5 includes the standby stage 54, the first transfer device 53, and the first movement device 55. The standby stage 54 includes the first standby region 54a and the second standby region 54b. On the first standby region 54a, the substrate W loaded from the batch processing section 4 is placed. The second standby region 54b is provided vertically adjacent to the first standby region 54a. On the second standby region 54b, the substrate W to be unloaded to the single-wafer processing section 6 is placed. The second standby region 54b includes the pure water supply 80 that supplies the first processing liquid to the top surface of the substrate W. The first transfer device 53 collectively transports the plurality of substrates W from the batch processing section 4 to the first standby region 54a. The first movement device 55 moves the substrate W from the first standby region 54a to the second standby region 54b. In this case, the time required for carrying the substrates W from the batch processing section 4 to the single-wafer processing section 6 is shortened. As a result, the throughput is improved.

### [Operation of Substrate Processing System]

### (Overall Operation)

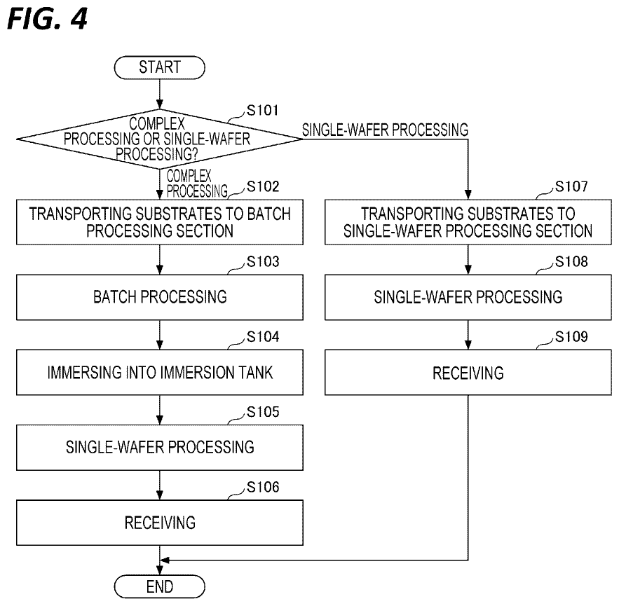

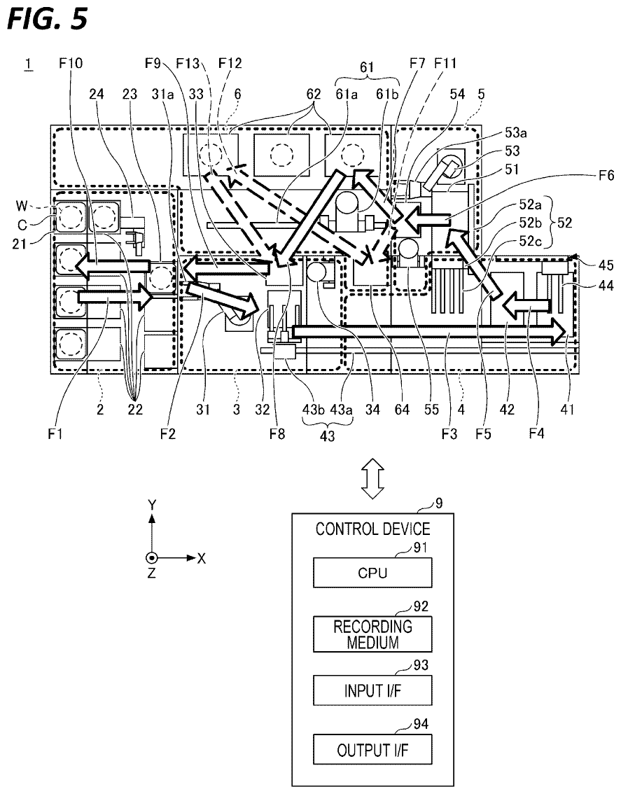

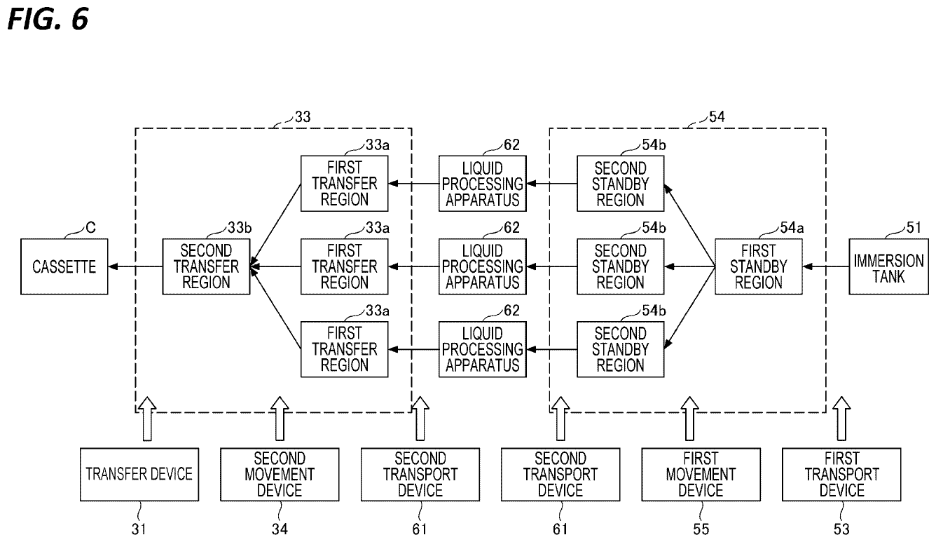

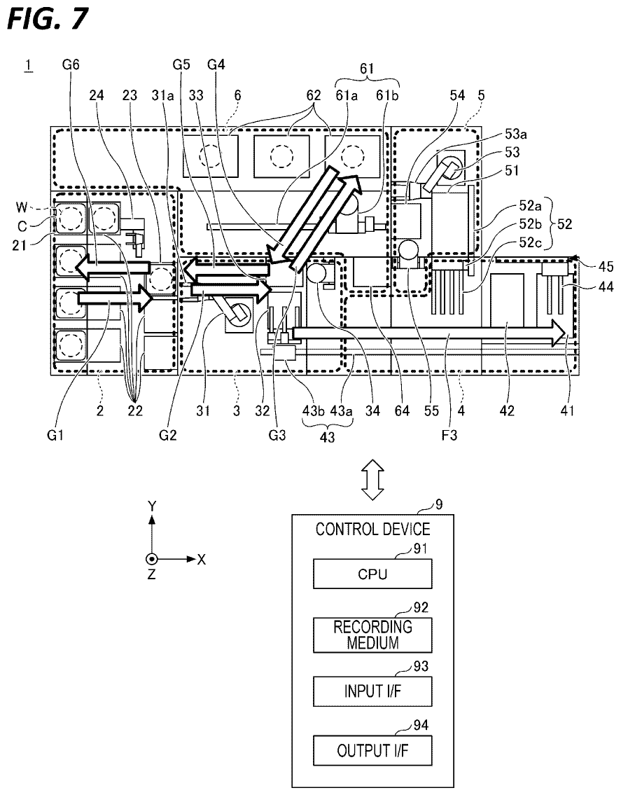

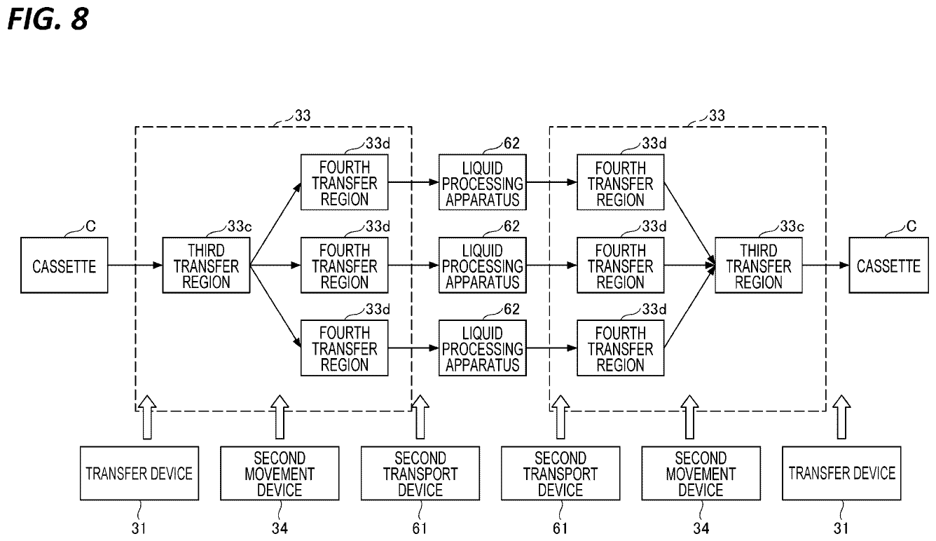

The operation of the substrate processing system 1 according to the embodiment, that is, the substrate processing method will be described with reference to FIGS. 4 to 8. FIG. 4 is a flow chart illustrating a substrate processing method according to the embodiment. FIG. 5 is a plan view illustrating the operation of complex processing. FIG. 6 is a view illustrating the transport flow of substrates W in complex processing. FIG. 7 is a plan view illustrating the operation of single-wafer processing. FIG. 8 is a view illustrating the transport flow of substrates W in single-wafer processing. The processing illustrated in FIG. 4 is performed under the control by the control device 9.

First, a cassette C, which accommodates a plurality of substrates W, is loaded into the loading/unloading section 2, and is placed on the load port 21. Inside the cassette C, substrates W are horizontally held, and are held at the second pitch P2 (P2=N×P1) in the vertical direction. N is a natural number of 2 or more. In the present embodiment, N is 2, but may be 3 or more.

Next, the cassette transport device 24 transports the cassette C from the load port 21 to the loader 23 (the arrow F1 in FIG. 5, and the arrow G1 in FIG. 7). When the cassette C is transported to the loader 23, the lid of the cassette C is opened by the lid opening/closing mechanism.

Next, the control device 9 controls each unit of the substrate processing system 1 so as to perform the processing illustrated in FIG. 4. The control device 9 controls each unit of the substrate processing system 1 so as to perform the processing illustrated in FIG. 4 whenever the cassette C is placed on the loader 23.

First, when the cassette C is transported to the loader 23, the control device 9 determines whether to perform complex processing or single-wafer processing on the plurality of substrates W accommodated in the cassette C based on information related to the cassette C (S101 in FIG. 4).

In S101 of FIG. 4, when it is determined that the complex processing is to be performed, the control device 9 controls each unit of the substrate processing system 1 so as to transport the substrates W accommodated in the cassette C to the batch processing section 4 (S102 in FIG. 4). Specifically, the transfer device 31 receives the substrates W accommodated in the cassette C, and transports the substrates W to the lot forming unit 32 (the arrow F2 in FIG. 5). Next, the lot forming unit 32 holds the plurality of substrates W at the first pitch P1 (P1=P2/N), and forms a lot L. One lot L is composed of, for example, substrates W of M cassettes C. Since the pitch of the substrates W is narrowed from the second pitch P2 to the first pitch P1, it is possible to increase the number of substrates W to be processed at one time. Next, the first lot transport device 43 receives the lot L from the lot forming unit 32, and transports the lot L to the processing tool 44 (the arrow F3 in FIG. 5).

Next, the processing tool 44 moves down from above the chemical liquid tank 41, immerses the lot L into the chemical liquid, and performs chemical liquid processing (S103 in FIG. 4). After that, the processing tool 44 moves up in order to lift up the lot L from the chemical liquid, and then moves in the horizontal direction (to the negative side in the X-axis direction) toward the top side of the rinse liquid tank 42 (the arrow F4 in FIG. 5).

Next, the processing tool 44 moves down from above the rinse liquid tank 42, immerses the lot L into the first rinse liquid, and performs rinse liquid processing (S103 in FIG. 4). Then, the processing tool 44 moves up in order to lift up the lot L from the first rinse liquid. Next, the first lot transport device 43 receives the lot L from the processing tool 44, and transfers the lot L to the second lot transport device 52.

Next, the transport arm 52c of the second lot transport device 52 moves in the horizontal direction (to the positive side in the Y-axis direction), moves down from above the immersion tank 51, and immerses the lot L into the second rinse liquid (S104 in FIG. 4, and the arrow F5 in FIG. 5). The plurality of substrates W of the lot L is held in the second rinse liquid until being lifted up from the second rinse liquid by the first transfer device 53. Since the substrates W exist below the liquid surface of the second rinse liquid, the surface tension of the second rinse liquid does not act on the substrates W, thereby preventing the collapse of the uneven patterns of the substrates W.

Next, the first transfer device 53 transports the substrates W of the lot L held by the transport arm 52c in the second rinse liquid, to the standby stage 54 (the arrow F6 in FIG. 5). The first transfer device 53 collectively transports the plurality of (e.g., two) substrates W to the first standby region 54a of the standby stage 54 (see, e.g., FIG. 6).

Next, the first movement device 55 transports the substrate W placed on the first standby region 54a, to the second standby region 54b provided corresponding to each of the upper, middle, and lower stages (see, e.g., FIG. 6). The first movement device 55 may move substrates W one by one, or may collectively move a plurality of substrates W. In the latter case, the first movement device 55 collectively transports the plurality of (e.g., two) substrates W.

Next, in each processing unit block 60, the second transfer device 61 receives the substrate W from the second standby region 54b of the standby stage 54, and transports the substrate W to the liquid processing apparatus 62 (the arrow F7 in FIG. 5, and FIG. 6).

Next, in each processing unit block 60, the liquid processing apparatus 62 processes the substrates W one by one with a liquid (S105 in FIG. 4). There may be a plurality of liquids, for example, pure water such as DIW, and a drying liquid having a lower surface tension than pure water. The drying liquid may be, for example, alcohol such as IPA. The liquid processing apparatus 62 supplies pure water and a drying liquid in this order to the top surface of the substrate W, thereby forming a liquid film of the drying liquid. The liquid processing apparatus 62 rotates the substrate W, and removes the drying liquid from the top surface of the substrate W by spin drying. Through the spin drying, the drying liquid is shaken off from the substrate W by a centrifugal force.

In the present embodiment, although the liquid processing apparatus 62 dries the substrate W through spin drying, the drying method is not particularly limited. The drying method may be any method capable of suppressing the collapse of the uneven pattern of the substrate W, and may be, for example, supercritical drying, scan drying, or water-repellent drying. In the supercritical drying, the drying liquid may be moved with the supercritical fluid, and it is possible to suppress the uneven pattern of the substrate W from being collapsed by the surface tension of the drying liquid. In the scan drying, as the supply position of the drying liquid is moved from the center of the substrate W toward the outer periphery of the substrate W, the substrate W is rotated, so that the liquid film is shaken off from the substrate W by a centrifugal force. Further, in the scan drying, the supply position of a drying gas such as N2 gas may be moved from the center of the substrate W toward the outer periphery of the substrate W so as to follow the supply position of the drying liquid.

Next, in each processing unit block 60, the second transfer device 61 receives the substrate W from the liquid processing apparatus 62, and transports the substrate W to the first transfer region 33a of the delivery stage 33 (the arrow F8 in FIG. 5, and FIG. 6).

When the liquid processing apparatus 62 is in an unavailable state during the transfer of the substrate W from the second standby region 54b to the liquid processing apparatus 62, the second transfer device 61 may transport the substrate W that is being transferred, to the retreat stage 64 (the arrow F11 in FIG. 5). After the substrate W is transferred to the retreat stage 64, when at least one of the three liquid processing apparatuses 62 is in an available state, the second transfer device 61 may transport the substrate W from the retreat stage 64 to the liquid processing apparatus 62 in the available state (the arrow F12 in FIG. 5). The second transfer device 61 receives the substrate W from the liquid processing apparatus 62, and transports the substrate W to the first transfer region 33a of the delivery stage 33 (the arrow F13 in FIG. 5).

Next, the second movement device 34 transports the substrate W placed on the first transfer region 33a provided corresponding to each of the upper, middle, and lower processing unit blocks 60, to the second transfer region 33b (see, e.g., FIG. 6). The second movement device 34 may move substrates W one by one, or may collectively move a plurality of substrates W. In the latter case, the second movement device 34 collectively transports the plurality of (e.g., two) substrates W.

Next, the substrates W are received by the transfer device 31 from the second transfer region 33b of the delivery stage 33, and are stored in the cassette C placed on the loader 23 (S106 in FIG. 4, the arrow F9 in FIG. 5, and FIG. 6).

Next, the cassette transport device 24 transports the cassette C from the loader 23 to the load port 21 (the arrow F10 in FIG. 5). The cassette C transported to the load port 21 is unloaded from the loading/unloading section 2 in a state where the plurality of substrates W is accommodated in the cassette C. The cassette C may be transported by the cassette transport device 24 from the loader 23 to the stocker 22, and may be temporarily stored in the stocker 22.

In S101 of FIG. 4, when it is determined that the single-wafer processing is to be performed, the control device 9 controls each unit of the substrate processing system 1 so as to transport the substrates W accommodated in the cassette C to the single-wafer processing section 6 (S107 in FIG. 4). Specifically, the substrates W accommodated in the cassette C are received by the transfer device 31, and are transported to the third transfer region 33c of the delivery stage 33 (the arrow G2 in FIG. 7, and FIG. 8).

Next, the second movement device 34 transports the substrate W placed on the third transfer region 33c, to the fourth transfer region 33d provided corresponding to each of the upper, middle, and lower stages (see, e.g., FIG. 8). The second movement device 34 may move substrates W one by one, or may collectively move a plurality of substrates W. In the latter case, the second movement device 34 collectively transports the plurality of (e.g., two) substrates W.

Next, in each processing unit block 60, the second transfer device 61 receives the substrate W from the fourth transfer region 33d of the delivery stage 33, and transports the substrate W to the liquid processing apparatus 62 (the arrow G3 in FIG. 7, and FIG. 8).

Next, like in S105 of FIG. 4, in each processing unit block 60, the liquid processing apparatus 62 processes the substrates W one by one with a liquid (S108 in FIG. 4).

Next, in each processing unit block 60, the second transfer device 61 receives the substrate W from the liquid processing apparatus 62, and transports the substrate W to the fourth transfer region 33d of the delivery stage 33 (the arrow G4 in FIG. 7, and FIG. 8).

Next, the second movement device 34 transports the substrate W placed on the fourth transfer region 33d provided corresponding to each of the upper, middle, and lower processing unit blocks 60, to the third transfer region 33c (see, e.g., FIG. 8). The second movement device 34 may move substrates W one by one, or may collectively move a plurality of substrates W. In the latter case, the second movement device 34 transports the plurality of (e.g., two) substrates W at one time.

Next, the substrates W are received by the transfer device 31 from the third transfer region 33c of the delivery stage 33, and are stored in the cassette C placed on the loader 23 (S109 in FIG. 4, the arrow G5 in FIG. 7, and FIG. 8).

Next, the cassette transport device 24 transports the cassette C from the loader 23 to the load port 21 (the arrow G6 in FIG. 7). The cassette C transported to the load port 21 is unloaded from the loading/unloading section 2 in a state where the plurality of substrates W is accommodated in the cassette C. The cassette C may be transported by the cassette transport device 24 from the loader 23 to the stocker 22, and may be temporarily stored in the stocker 22.

### (Operation of First Movement Device)

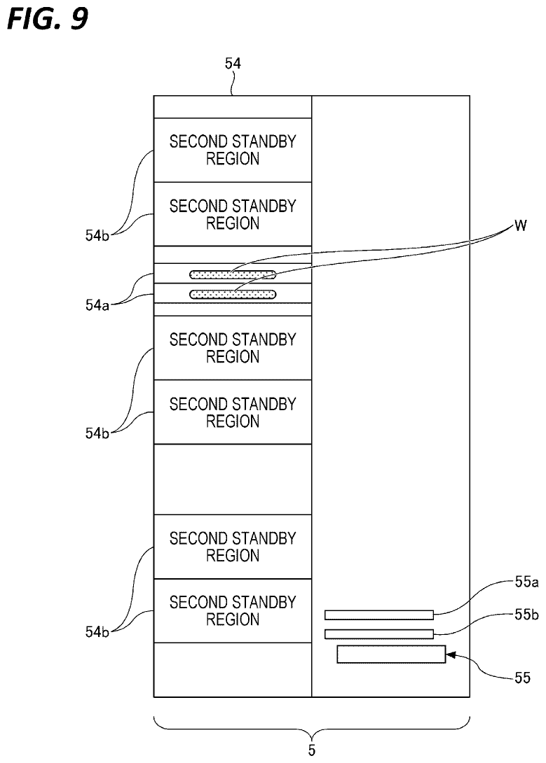

An example of the operation of the first movement device 55, in which the first movement device 55 transfers substrates W for movement from the first standby regions 54a of the standby stage 54 to the second standby regions 54b will be described with reference to FIGS. 9 to 15. FIGS. 9 to 15 are views illustrating the movement operation of substrates W in the standby stage 54. FIGS. 9 to 15 illustrate a case where the first movement device 55 includes an upper arm 55a and a lower arm 55b, and the substrates W are moved by the upper arm 55a and the lower arm 55b.

First, as illustrated in FIG. 9, one substrate W is loaded into each of two first standby regions 54a by the first transfer device 53. Each substrate W is, for example, a substrate processed in the batch processing section 4.

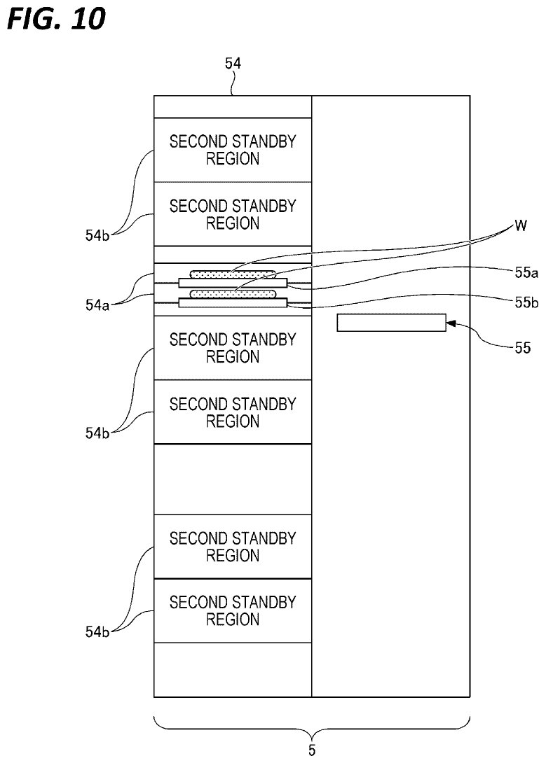

Next, as illustrated in FIG. 10, the first movement device 55 inserts the upper arm 55a into one first standby region 54a, and receives the substrate W placed on one first standby region 54a. Also, the first movement device 55 inserts the lower arm 55b into the other first standby region 54a, and receives the substrate W placed on the other first standby region 54a.

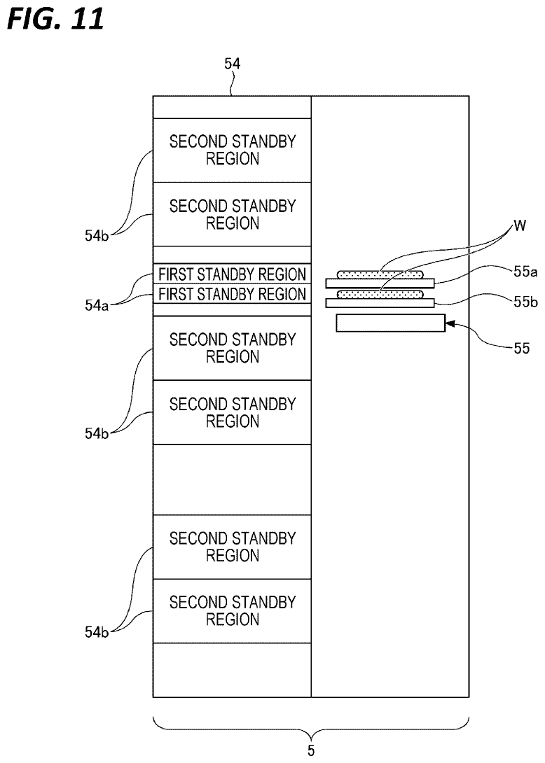

Next, as illustrated in FIG. 11, the first movement device 55 pulls out the upper arm 55a holding the substrate W from one first standby region 54a, and pulls out the lower arm 55b holding the substrate W from the other first standby region 54a. Accordingly, the substrates W are simultaneously taken out of one first standby region 54a and the other first standby region 54a.

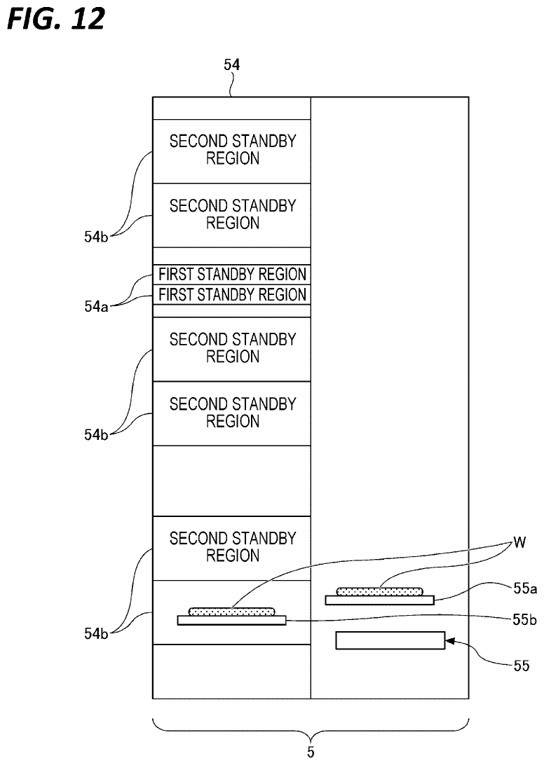

Next, as illustrated in FIG. 12, the first movement device 55 moves down to the same height as one second standby region 54b provided corresponding to the lower processing unit block 60, inserts the lower arm 55b to one second standby region 54b, and transfers the substrate W to one second standby region 54b. Accordingly, one substrate W is loaded into one second standby region 54b provided corresponding to the lower processing unit block 60.

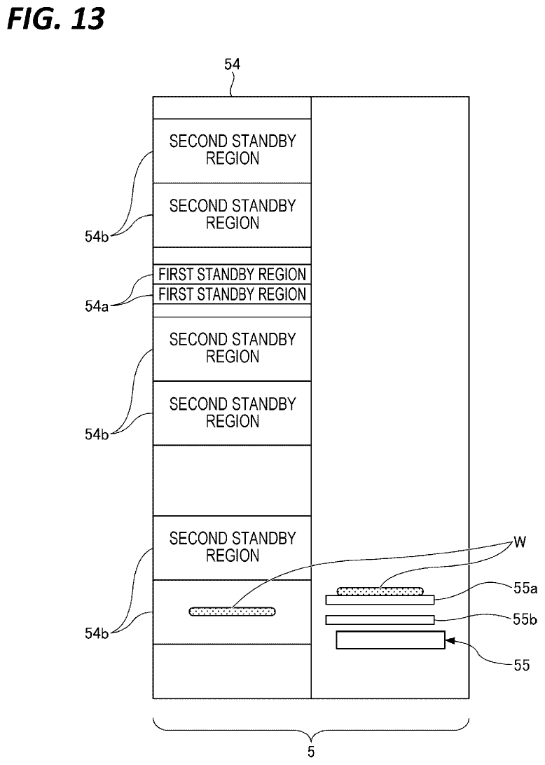

Next, as illustrated in FIG. 13, the first movement device 55 pulls out the lower arm 55b from one second standby region 54b.

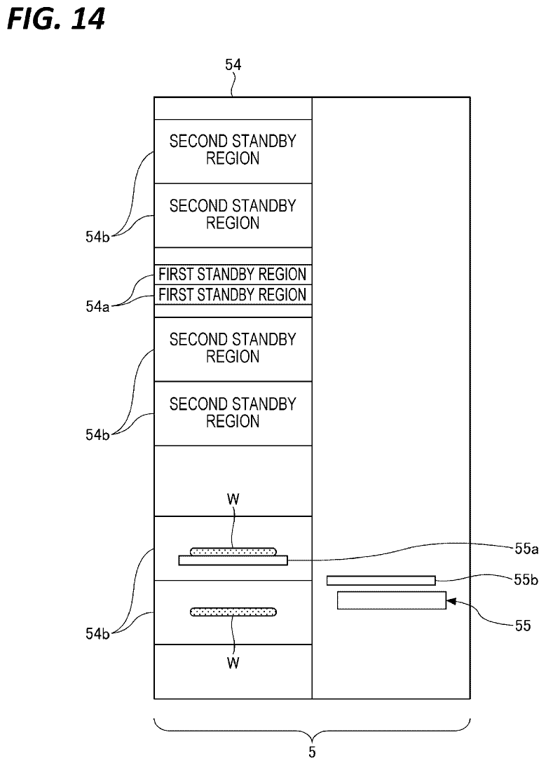

Next, as illustrated in FIG. 14, the first movement device 55 moves up to the same height as the other second standby region 54b provided corresponding to the lower processing unit block 60, inserts the upper arm 55a into the other second standby region 54b, and transfers the substrate W to the other second standby region 54b. Accordingly, one substrate W is loaded into the other second standby region 54b provided corresponding to the lower processing unit block 60.

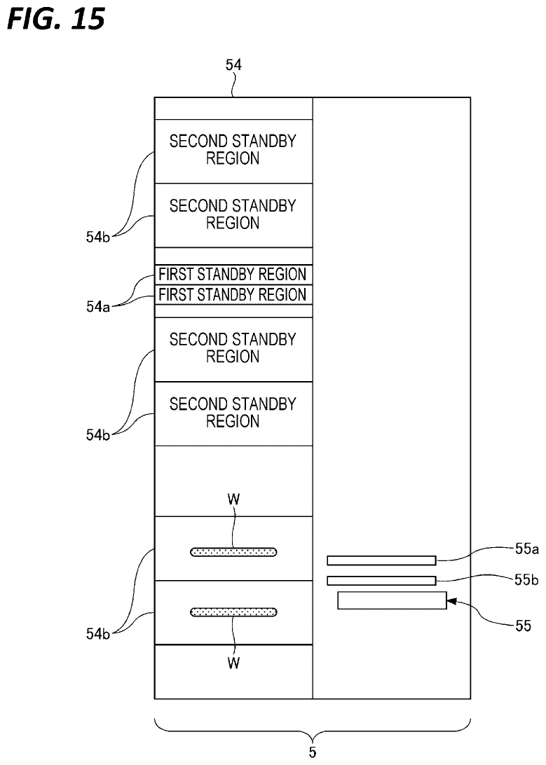

Next, as illustrated in FIG. 15, the first movement device 55 pulls out the upper arm 55a from the other second standby region 54b.

Consequently, two substrates W are collectively moved from the first standby regions 54a to the second standby regions 54b. In this case, the time required for carrying substrates W is shortened. As a result, the throughput is improved.

Also, the same may also apply to a case where substrates W are moved from the first standby regions 54a to the second standby regions 54b provided corresponding to the upper and middle processing unit blocks 60. Also, the first replacement device 55 may transfer the substrate W held by the upper arm 55a, and the substrate W held by the lower arm 55b, to the second standby regions 54b provided corresponding to a separate processing unit block 60.

### (Operation of Second Movement Device)

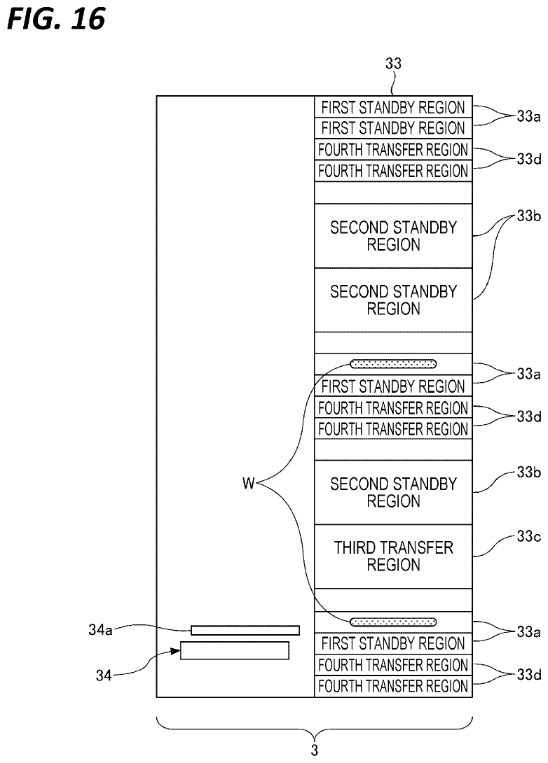

An example of the operation of the second replacement device 34, in which the second replacement device 34 moves substrates W from the first transfer regions 33a of the delivery stage 33 to the second transfer region 33b will be described with reference to FIGS. 16 to 24. FIGS. 16 to 24 are views illustrating the movement operation of substrates W in the delivery stage 33. FIGS. 16 to 24 illustrate a case where the second movement device 34 includes an arm 34a, and the substrates W are moved by the arm 34a.

First, as illustrated in FIG. 16, the second transfer device 61 loads one substrate W into the first transfer region 33a provided corresponding to the middle processing unit block 60, and one substrate W into the first transfer region 33a provided corresponding to the lower processing unit block 60. Each substrate W is, for example, a substrate processed in the single-wafer processing section 6.

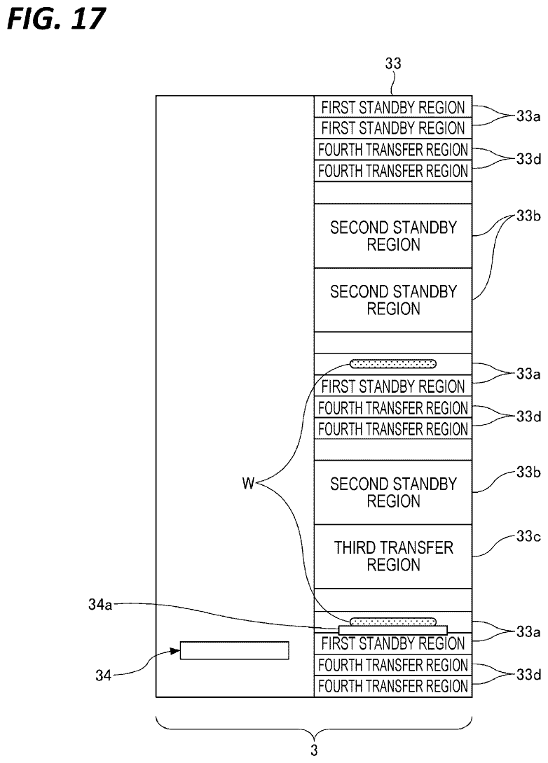

Next, as illustrated in FIG. 17, the second movement device 34 inserts the arm 34a into the first transfer region 33a provided corresponding to the lower processing unit block 60, and receives the substrate W placed on the first transfer region 33a.

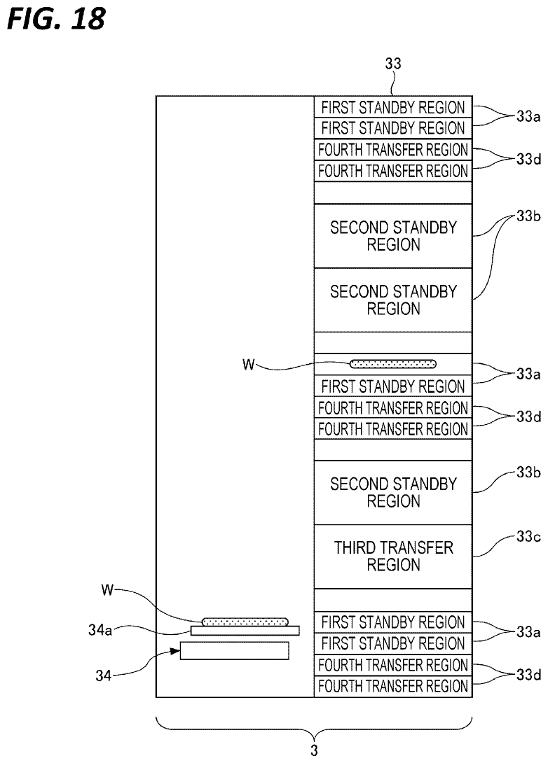

Next, as illustrated in FIG. 18, the second movement device 34 pulls out the arm 34a holding the substrate W from the first transfer region 33a. Accordingly, the substrate W is taken out of the first transfer region 33a.

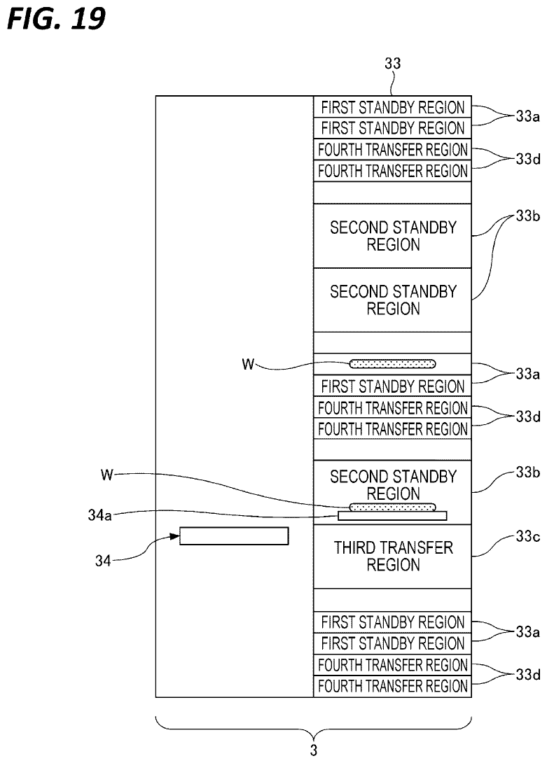

Next, as illustrated in FIG. 19, the second movement device 34 moves up to the same height as one of the three second transfer regions 33b, inserts the arm 34a into the second transfer region 33b, and transfers the substrate W to the second transfer region 33b. Accordingly, a first substrate W is loaded into the second transfer region 33b.

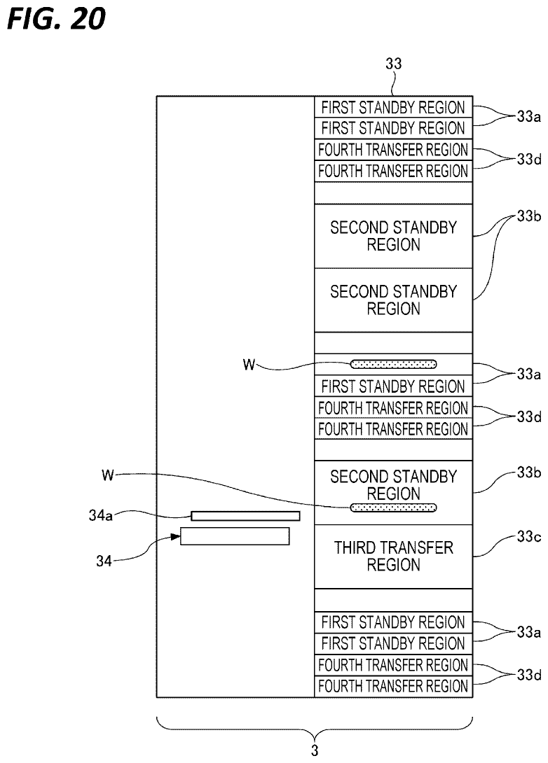

Next, as illustrated in FIG. 20, the second movement device 34 pulls out the arm 34a from the second transfer region 33b.

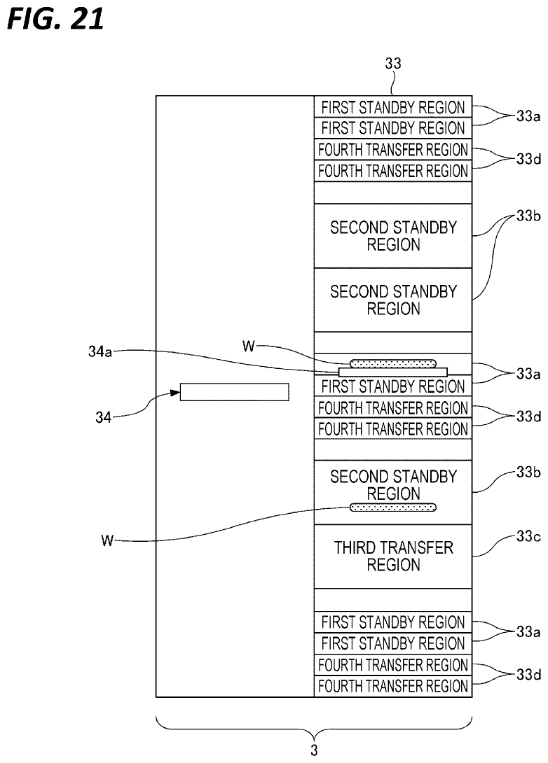

Next, as illustrated in FIG. 21, the second movement device 34 moves up to the same height as the first transfer region 33a provided corresponding to the middle processing unit block 60, inserts the arm 34a into the first transfer region 33a, and receives the substrate W placed on the first transfer region 33a.

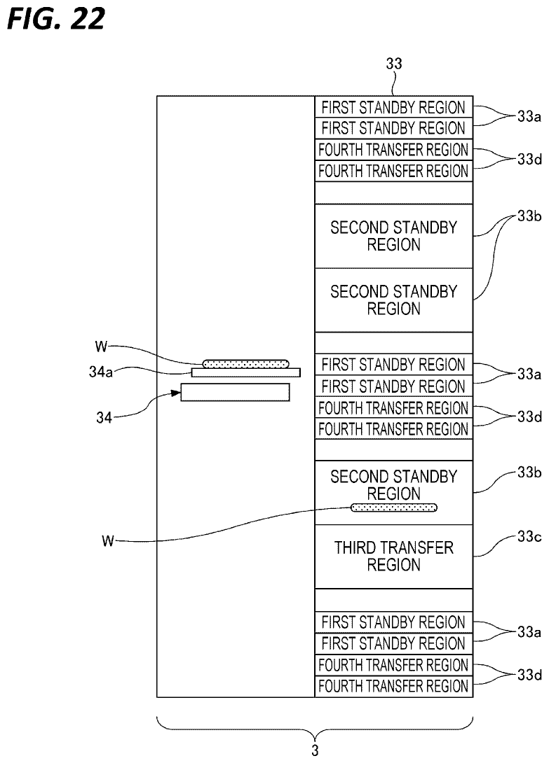

Next, as illustrated in FIG. 22, the second movement device 34 pulls out the arm 34a holding the substrate W from first transfer region 33a. Accordingly, the substrate W is taken out of the first transfer region 33a.

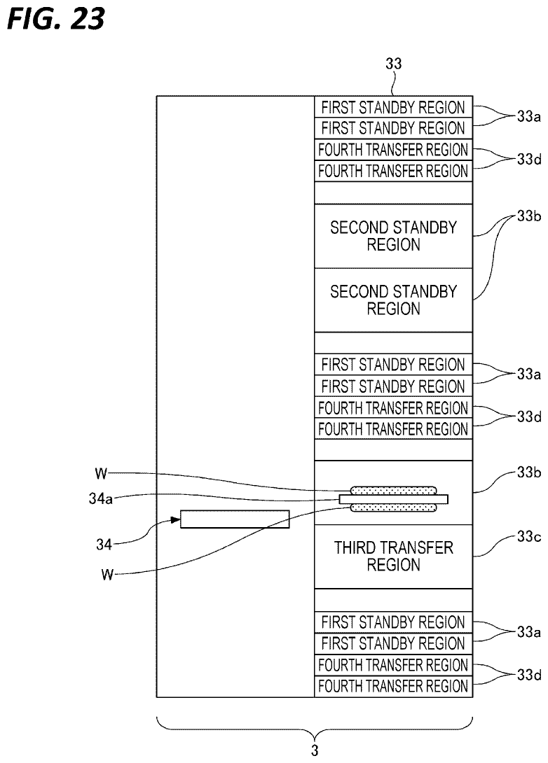

Next, as illustrated in FIG. 23, the second movement device 34 moves down to the same height as the second transfer region 33b where the first substrate W is loaded, inserts the arm 34a into the second transfer region 33b, and transfers the substrate W to the second transfer region 33b. Accordingly, a second substrate W is loaded into the second transfer region 33b.

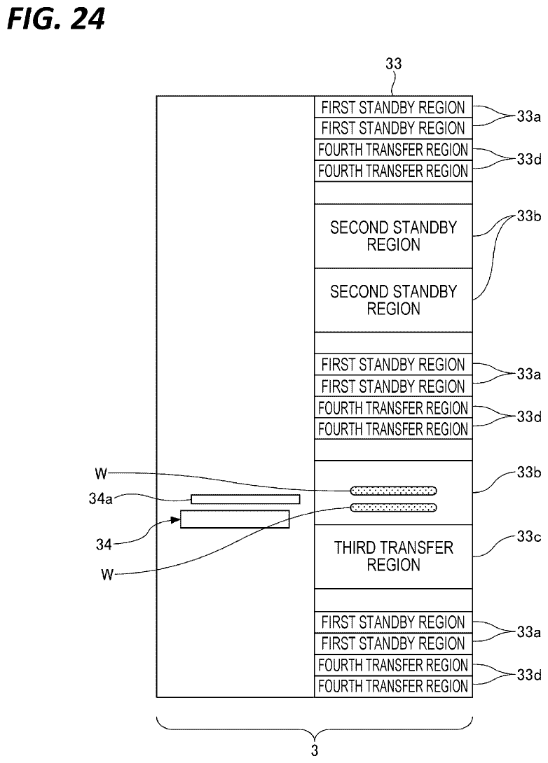

Next, as illustrated in FIG. 24, the second movement device 34 pulls out the arm 34a from the second transfer region 33b.

Consequently, the substrates W are moved from the first transfer regions 33a to the second transfer region 33b. Also, when a predetermined number of (e.g., 25) substrates W are loaded into the second transfer region 33b, the transfer device 31 collectively transports a predetermined number of substrates W from the second transfer region 33b to the cassette C placed on the loader 23.

Also, the same may also apply to a case where a substrate W is moved from the first transfer region 33a provided corresponding to the upper processing unit block 60, to the second transfer region 33b.

In the above-described substrate processing method according to the embodiment, the first transfer device 53 collectively transports a plurality of substrates W from the batch processing section 4 to the first standby region 54a. Next, the first movement device 55 moves substrates W from the first standby regions 54a to the second standby regions 54b. Then, the pure water supply 80 supplies pure water to the top surface of the substrate W placed on the second standby region 54b, thereby forming the liquid film on the top surface of the substrate W. Next, the second transfer device 61 transports the substrate W on which the liquid film is formed, from the second standby region 54b to the single-wafer processing section 6. In this case, the time required for carrying the substrates W from the batch processing section 4 to the single-wafer processing section 6 is shortened. As a result, the throughput is improved.

According to the present disclosure, the throughput may be improved.

From the foregoing content, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing system comprising:
a loading/unloading section configured to load and unload a cassette that accommodates a plurality of substrates;
a batch processing section configured to collectively process the plurality of substrates;
a single-wafer processing section configured to process the plurality of substrates one by one;
a substrate transfer section configured to transfer the plurality of substrates from the loading/unloading section to the batch processing section and the single-wafer processing section; and
a substrate standby section configured to transfer the plurality of substrates from the batch processing section to the single-wafer processing section,
wherein the substrate standby section includes:
a standby stage including a first standby region configured to dispose thereon the substrate loaded from the batch processing section, and a second standby region provided vertically adjacent to the first standby region and configured to dispose thereon the substrate to be unloaded to the single-wafer processing section;
a first transport device configured to collectively transport the plurality of substrates from the batch processing section to the first standby region; and
a first movement device configured to move the substrate from the first standby region to the second standby region,
wherein the second standby region includes a first processing liquid supply configured to supply a first processing liquid to a top surface of the substrate.

2. The substrate processing system according to claim 1, wherein the substrate transfer section includes:
a transfer stage including a first transfer region configured to dispose thereon the substrate loaded from the single-wafer processing section, and a second transfer region provided vertically adjacent to the first transfer region and configured to dispose thereon the substrate to be unloaded to the loading/unloading section;
a second movement device configured to move the substrate from the first transfer region to the second transfer region; and
a transfer device configured to transfer the substrate from the second transfer region to the loading/unloading section.

3. The substrate processing system according to claim 2, wherein the single-wafer processing section includes:
a liquid processing apparatus configured to process the plurality of substrates one by one; and
a second transport device configured to transport the substrate from the liquid processing apparatus to the first transfer region.

4. The substrate processing system according to claim 3, wherein the single-wafer processing section includes a retreat stage provided at a location accessible by the second transport device and configured to dispose thereon the substrate unloaded from the substrate standby section, and
the second transport device is configured to transport the substrate that is being transferred, to the retreat stage, when the liquid processing apparatus is in an unavailable state during transport of the substrate from the substrate standby section to the liquid processing apparatus.

5. The substrate processing system according to claim 4, wherein the retreat stage includes a second processing liquid supply configured to supply a second processing liquid to a top surface of the substrate.

6. The substrate processing system according to claim 3, wherein a plurality of liquid processing apparatuses is provided side by side in a vertical direction.

7. The substrate processing system according to claim 2, wherein the transfer stage further includes:
a third transfer region configured to dispose thereon the substrate loaded from the loading/unloading section; and
a fourth transfer region configured to dispose thereon the substrate to be unloaded to the single-wafer processing section,
the transfer device is configured to transfer the substrate from the loading/unloading section to the third transfer region, and
the second movement device is configured to move the substrate from the third transfer region to the fourth transfer region.

8. The substrate processing system according to claim 7, wherein the transfer stage further includes a fifth transfer region configured to dispose thereon the substrate to be unloaded to the batch processing section, and
the transfer device is configured to transfer the substrate from the loading/unloading section to the fifth transfer region.

9. The substrate processing system according to claim 8, wherein the transfer device is configured to transfer a plurality of substrates accommodated in the cassette, to the third transfer region or the fifth transfer region based on information related to the cassette loaded into the loading/unloading section.

10. The substrate processing system according to claim 2, wherein the transfer device is configured to collectively transfer the plurality of substrates.

11. The substrate processing system according to claim 1, wherein the first movement device is configured to collectively transport the plurality of substrates.

12. A substrate processing method comprising:
providing a substrate processing system including:
a loading/unloading section that loads and unloads a cassette that accommodates a plurality of substrates;
a batch processing section that collectively processes the plurality of substrates;
a single-wafer processing section that processes the plurality of substrates one by one;
a substrate transfer section that transfers the plurality of substrates from the loading/unloading section to the batch processing section and the single-wafer processing section; and
a substrate standby section that transfers the plurality of substrates from the batch processing section to the single-wafer processing section, and includes a first standby region and a second standby region that are provided side by side in a vertical direction;
collectively transporting the plurality of substrates from the batch processing section to the first standby region;
moving the plurality of substrates from the first standby region to the second standby region;
supplying a first processing liquid to a top surface of each of the plurality of substrate placed on the second standby region, thereby forming a liquid film on the top surface; and
transporting the substrate having the liquid film formed thereon, from the second standby region to the single-wafer processing section.
